(19) United States
(12) Patent Application Publication
(10) Pub. No.: US 2007/0126108 A1
(43) Pub. Date: Jun. 7, 2007

(54) EXTERNAL CONNECTION STRUCTURE FOR SEMICONDUCTOR PACKAGE, AND METHOD FOR MANUFACTURING THE SAME

(75) Inventors: Katsumi Yamazaki, Nagano-shi, Nagano (JP); Masato Tanaka, Nagano-shi, Nagano (JP)

Correspondence Address: RANKIN, HILL, PORTER & CLARK LLP, 4080 ERIE STREET, WILLOUGHBY, OH, 44094-7836, US

(73) Assignee: SHINKO ELECTRIC INDUSTRIES CO., LTD., Nagano-shi (JP)

(21) Appl. No.: 11/566,436

(22) Filed: Dec. 4, 2006

(30) Foreign Application Priority Data
Dec. 6, 2005 (JP) 2005-351843

(51) Int. Cl. H01L 23/48

(52) U.S. Cl. 257/690

(57) ABSTRACT

Conductive posts to be connected with external connection terminals are formed on a conductive pattern formed on a substrate, and an insulating resin sheet is laminated on the conductive pattern having the conductive posts formed thereon, so as to be flush with the end faces of the conductive posts 3 exposed to the substrate surface.

This application claims foreign priority based on Japanese Patent application No. 2005-351843, filed Dec. 6, 2005, the content of which is incorporated herein by reference in its entirety.

### BACKGROUND OF THE INVENTION

1. Field of the Invention

The present invention relates to an external connection structure for a semiconductor package, in which a conductive pattern for forming solder bumps as external connection terminals is formed in the outermost layer of the semiconductor package, and a method for manufacturing the external connection structure.

2. Description of the Related Art

FIG. 3 shows a state in which solder bumps 52 are formed as external connection terminals on a conductive pattern 54 formed in the outermost layer of the semiconductor package. In FIG. 3, when the solder bumps 52 are to be formed on the outermost layer of a semiconductor package 51, the conductive pattern 54 is formed on a substrate 53. After this, a solder resist 55 is applied by a squeegee to the conductive pattern 54, and openings are formed in accordance with the positions to form the solder bumps 52. The conductive pattern 54, as exposed from the openings of the solder resist 55, is plated with nickel and gold (Ni/Au), and a solder paste is printed on a plated face 56. Then, the semiconductor package is cured in a heating oven to form the solder bumps 52.

In the aforementioned process for manufacturing the semiconductor package, when the solder paste is applied by a screen-printing to the openings of the solder resist 55, the printing irregularities of the solder paste may be caused according to the state of the solder resist covering the substrate surface. Then, the quantity of the solder paste to be applied to the openings may vary to cause a height variance of the solder bumps 52.

Specifically, since a liquid resist is used for the solder resist 55, thickness of the solder resist 54 varies due to the concentration of the conductive pattern, as shown in FIG. 3. This raises a problem that the thickness especially around the openings is liable to vary.

When feeding amounts of the solder paste at the positions in which the solder bumps are formed vary as described above, resultantly the height variance is made when the solder bumps 52 are formed.

Furthermore, other than the problem of the thickness variance of the solder resist layer, the problem is also raised in the reliability of the solder resist layer as an electric insulating layer because the solder resist layer is easily peeled off.

### SUMMARY OF THE INVENTION

The present invention has been made in view of the above circumstances, and provides an external connection structure for a highly reliable semiconductor package and a method for manufacturing the external connection structure, in which a step (height difference) between a conductive pattern to be connected with external connection terminals and a surrounding insulating layer is eliminated so as to eliminate the height variance of the external connection terminals.

In some implementations, an external connection structure of a semiconductor package of the invention, comprising;

a conductive pattern formed on a substrate;

conductive posts for connecting external connection terminal that are formed on the outermost layer of the semiconductor package, the conductive posts being formed on the conductive pattern; and

an insulating resin laminated on the conductive pattern,

wherein the insulating resin is flush with end faces of the conductive posts that are exposed to the substrate surface.

In some implementations, a method of the invention for manufacturing an external connection structure of a semiconductor package, the method comprising:

performing electroless plating on a substrate so as to form a plated seed layer;

forming a first plated resist pattern layer for forming a conductive pattern on the plated seed layer;

performing electrolytic plating for applying a plating metal thickly to exposed portions of the plated seed layer thereby to form the conductive pattern;

polishing a surface of the substrate so that the conductive pattern and the first plated resist pattern layer becomes flush with each other;

forming a second plated resist pattern layer for forming conductive posts to be connected with external connection terminals on the conductive pattern of the substrate surface;

performing electrolytic plating for applying a plating plate thickly to exposed portions of the conductive pattern thereby to form the conductive posts;

removing the first plated resist pattern layer and the second plated resist pattern layer so as to expose the conductive pattern on which the conductive posts are formed;

removing the plated seed layer exposed from areas other than the conductive pattern;

laminating an insulating resin on the conductive pattern on which the conductive posts are formed;

flattening the substrate surface so that end faces of the conductive posts are exposed to be flush with the insulating resin; and

forming the external connection terminals on the end faces of the conductive posts that are exposed to the substrate surfaces.

In the method for manufacturing an external connection structure of a semiconductor package, the step of laminating the insulating resin on the conductive pattern includes laminating an insulating resin sheet or printing an insulating resin to laminate.

In the method for manufacturing an external connection structure of a semiconductor package, the step of flattening the substrate surface includes performing at least one of mechanical polishing or dry etching on the insulated resin laminated on the conductive pattern or the conductive posts so as to remove the excessive resin.

### BRIEF DESCRIPTION OF THE DRAWINGS

FIG. 1 is an explanatory section of the outermost layer of a semiconductor package.

FIGS. 2A-2J are explanatory diagrams showing steps of manufacturing an external connection terminal connecting structure of the semiconductor package.

FIG. 3 is an explanatory section showing a discrepancy of a semiconductor package of the related art.

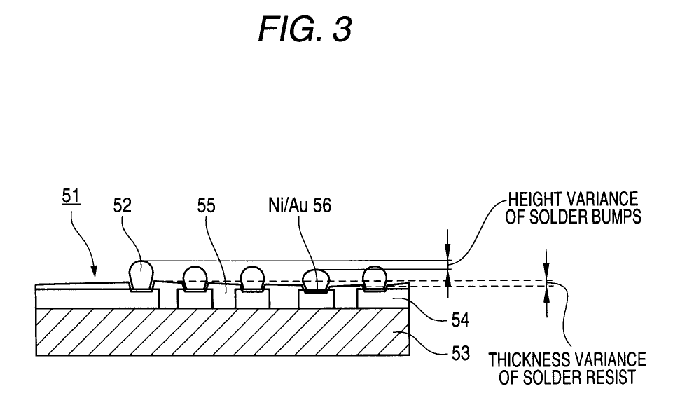

### DESCRIPTION OF THE PREFERRED EMBODIMENTS

In the following, the best embodiments of an external connection terminal structure of a semiconductor package according to the invention and its manufacturing method will be described in detail with reference to the accompanying drawings. The external connection terminal forming structure of the semiconductor package of this embodiment is described on the external connection terminal forming structure, in which a conductive pattern for forming external connection terminals is formed on the outermost layer of the semiconductor package.

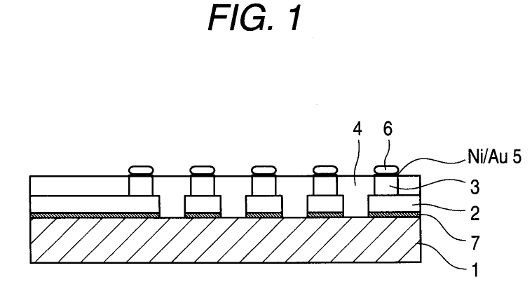

The external connection terminal forming structure of the semiconductor package is described with reference to FIG. 1.

A substrate 1 is a resin substrate. On the outermost layer of the semiconductor package, there is formed a conductive pattern 2 for forming the external connection terminal. The substrate 1 on which the conductive pattern 2 is formed may be either a single-layer wiring substrate or a multi-layer wiring substrate.

On the conductive pattern 2, there are formed conductive posts 3 for connecting the external connection terminals. On the conductive pattern 2 having the conductive posts 3 formed thereon, an insulating resin 4 is laminated so that the insulating resin layer becomes flat while exposing the post end face to the outside. This post end face is plated with nickel and gold (Ni/Au) sequentially, and a solder paste is printed on that plated face 5, and is jointed by applying heat to form solder bumps 6.

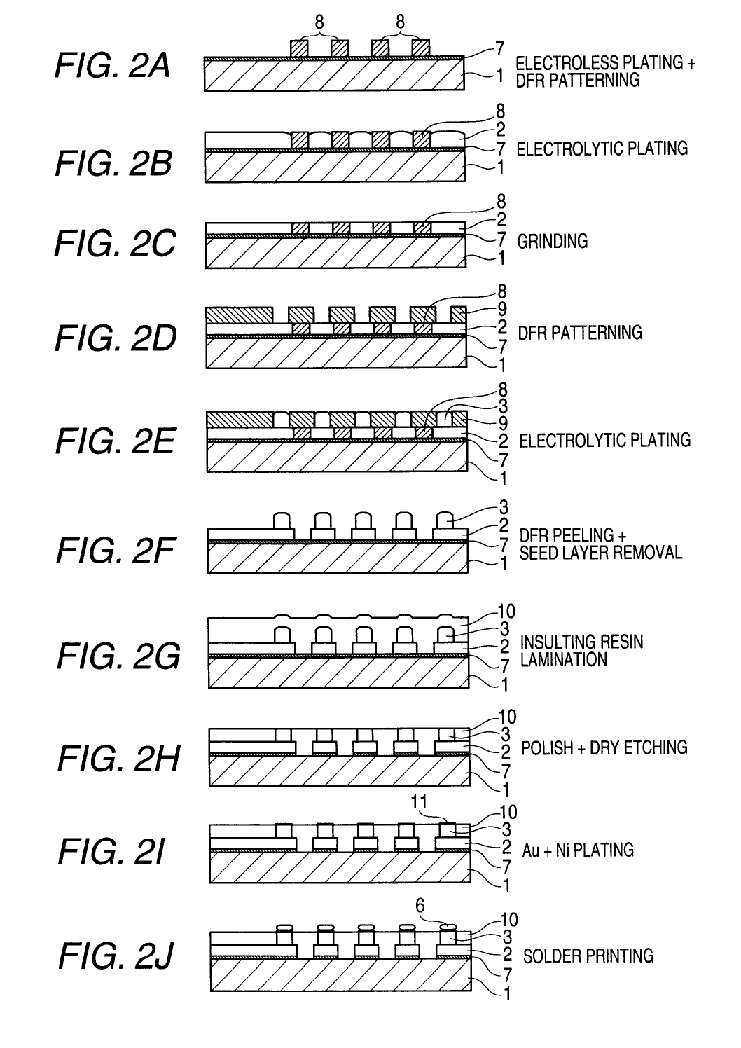

Next, a method for manufacturing the external connection structure of the semiconductor package is described with reference to FIGS. 2A-2J.

In FIG. 2A, electroless copper plating is applied to the substrate 1 is subjected to form a plated seed layer 7. On this plated seed layer 7, there is formed a plated resist pattern 8 for forming the conductive pattern 2. Specifically, the surface of the plated seed layer 7 is coated with a photosensitive resist film (dry film resist), and patterning is performed on the photosensitive resist film by a photolithography process thereby to form the plated resist pattern 8.

Next, in FIG. 2B, an electrolytic copper plating is applied by using the plated seed layer 7 as a electric feeding layer, so that the electrolytic copper-plated layer is formed thick on the exposed portion of the plated seed layer 7 thereby to form the conductive pattern 2. Next, in FIG. 2C, the substrate surface is polished to make the conductive pattern 2 and the plated resist pattern 8 flush with each other. This polishing process is performed by mechanical polishing process.

Next, in FIG. 2D, a plated resist pattern 9 is formed on the conductive pattern 2 to form the conductive posts 3 for connecting the external connection terminals. Specifically, the substrate surface, on which the conductive pattern 2 and the plated resist pattern 8 are polished to be flush with each other, is coated with the photosensitive resist film (dry film resist). Then, patterning is performed on the photosensitive resist film by a photolithography process to form the plated resist pattern 9, in which portions for forming the conductive posts 3 are recessed and in which the conductive pattern 2 is exposed from the inner bottom face thereof. Next, in FIG. 2E, an electrolytic copper plating is performed to plate the exposed portion of the conductive pattern 2 with a thick electrolytic copper layer thereby to form the conductive posts 3.

Next, in FIG. 2F, the plated resist patterns 8 and 9 are removed to expose the conductive pattern 2 having the conductive posts 3, and the plated seed layer 7 is etched off at its exposed portions excepting the conductive pattern 2.

Next, in FIG. 2G, an insulating resin sheet 10 of an epoxy group, for example, is laminated on the conductive pattern 2 having the conductive posts 3, and is subjected to a vacuum lamination while being heated and pressed. End faces of the conductive posts 3 on the substrate surface are completely covered by the insulating resin sheet 10. Here, the lamination of the insulating resin sheet 10 may be replaced by lamination of an insulating resin of an epoxy group on the substrate surface by printing.

Next, in FIG. 2H, the post end faces of the conductive posts 3 are exposed and flattened to be flush with the insulating resin sheet 10. Specifically, the insulating resin sheet 10, which is laminated on the conductive pattern or the conductive posts, is at least mechanically polished (or buffed) or dry-etched on the substrate surface, so that the substrate surface is flattened until the end faces of the conductive posts 3 are exposed. Both the mechanical polishing and the dry-etching may be performed to ensure this flattening of the substrate surface until the end faces of the conductive posts 3 are exposed.

Next, in FIG. 2I, the post end faces of the conductive posts 3, as exposed to the substrate surface from the insulating resin layer, are plated with nickel and gold (Ni/Au) in this order, thereby to form plated faces 11. Finally, in FIG. 2J, these plated faces 11 are printed with the solder paste, and are cured in a heating oven so that the solder bumps 6 are jointed.

According to the external connection terminal connecting structure manufacturing method thus far described, the end faces of the conductive posts 3, as exposed from the insulating resin sheet 10, are evenly formed so that the printing irregularities of the solder paste, as might otherwise be caused by the thickness variance of the insulating resin layer, can be eliminated. Thus, it is possible to make uniform the heights of the solder bumps 6 formed on the end faces of the conductive posts 3. Moreover, the substrate surface is flattened by at least mechanically polishing or dry etching the insulating resin sheet laminated on the conductive pattern 2 or the conductive posts 3, so that the end faces of the conductive posts 3 are exposed. Thus, it is possible to improve the printing precision of the solder paste to be printed for forming the external connection terminals. Moreover, the insulating resin sheet 10 is more firmly laminated than the solder resist on the substrate surface, so that it becomes hard to peel off the insulating resin sheet 10 from the substrate surface thereby to improve the reliability of the semiconductor package.

According to the external connection structure of the aforementioned semiconductor package and the method for manufacturing the structure, the conductive posts for connecting the external connection terminals are formed on the conductive pattern formed on the substrate, and the insulating resin is laminated on the conductive pattern having the conductive posts formed thereon, to be flush with the end faces of the conductive posts exposed to the substrate surface. Therefore, the thickness of the insulating resin layer is hardly caused to vary by the concentration of the conductive pattern, and the end faces of the conductive posts, as exposed from the insulating resin, are uniformly flush with one another. It is, therefore, possible to make the heights of the external connection terminals, as formed on the end faces of the conductive posts, uniform. Furthermore, as compared with the solder resist layer formed by applying the liquid resist, the insulating resin layer is hard to be peeled off so that the reliability as the electric insulating layer can be improved.

Especially, by at least mechanically polishing or dry-etching the insulated resin layer laminated on the conductive pattern or the conductive posts thereby to flatten the substrate surface until the conductive post end faces are exposed, it is possible to improve the printing precision of the solder paste to be printed for forming the external connection terminals.

It will be apparent to those skilled in the art that various modifications and variations can be made to the described preferred embodiments of the present invention without departing from the spirit or scope of the invention. Thus, it is intended that the present invention cover all modifications and variations of this invention consistent with the scope of the appended claims and their equivalents.

What is claimed is:

1. An external connection structure of a semiconductor package, comprising;
a conductive pattern formed on a substrate;
conductive posts for connecting external connection terminal that are formed on the outermost layer of the semiconductor package, the conductive posts being formed on the conductive pattern; and
an insulating resin laminated on the conductive pattern,
wherein the insulating resin is flush with end faces of the conductive posts that are exposed to the substrate surface.

2. A method for manufacturing an external connection structure of a semiconductor package, the method comprising:
performing electroless plating on a substrate so as to form a plated seed layer;
forming a first plated resist pattern layer for forming a conductive pattern on the plated seed layer;
performing electrolytic plating for applying a plating metal thickly to exposed portions of the plated seed layer thereby to form the conductive pattern;
polishing a surface of the substrate so that the conductive pattern and the first plated resist pattern layer becomes flush with each other;
forming a second plated resist pattern layer for forming conductive posts to be connected with external connection terminals on the conductive pattern of the substrate surface;
performing electrolytic plating for applying a plating plate thickly to exposed portions of the conductive pattern thereby to form the conductive posts;
removing the first plated resist pattern layer and the second plated resist pattern layer so as to expose the conductive pattern on which the conductive posts are formed;
removing the plated seed layer exposed from areas other than the conductive pattern;
laminating an insulating resin on the conductive pattern on which the conductive posts are formed;
flattening the substrate surface so that end faces of the conductive posts are exposed to be flush with the insulating resin; and
forming the external connection terminals on the end faces of the conductive posts that are exposed to the substrate surfaces.

3. The method for manufacturing an external connection structure of a semiconductor package as claimed in claim 2, wherein the step of laminating the insulating resin on the conductive pattern includes laminating an insulating resin sheet or printing an insulating resin to laminate.

4. The method for manufacturing an external connection structure of a semiconductor package as claimed in claim 2, wherein the step of flattening the substrate surface includes performing at least one of mechanical polishing or dry etching on the insulated resin laminated on the conductive pattern or the conductive posts so as to remove the excessive resin.
